(19) United States
(12) Patent Application Publication
(10) Pub. No.: US 2006/0250836 A1
(43) Pub. Date: Nov. 9, 2006

(54) Rewriteable memory cell comprising a diode and a resistance-switching material

(75) Inventors: S. Brad Herner, San Jose, CA (US); Christopher J. Petti, Mountain View, CA (US)

Correspondence Address: MATRIX SEMICONDUCTOR, INC., 3230 SCOTT BOULEVARD, SANTA CLARA, CA, 95054, US

(73) Assignee: Matrix Semiconductor, Inc., Santa Clara, CA (US)

(21) Appl. No.: 11/125,939

(22) Filed: May 9, 2005

(51) Int. Cl. G11C 11/00

(52) U.S. Cl. 365/148

(57) ABSTRACT

In a novel rewriteable nonvolatile memory cell formed above a substrate, a diode is paired with a reversible resistance-switching material, preferably a metal oxide or nitride such as, for example, NiO, Nb₂O₅, TiO₂, HfO₂, Al₂O₃, MgOₓ, CrO₂, VO, BN, and AlN. In preferred embodiments, the diode is formed as a vertical pillar disposed between conductors. Multiple memory levels can be stacked to form a monolithic three dimensional memory array. In some embodiments, the diode comprises germanium or a germanium alloy, which can be deposited and crystallized at relatively low temperatures, allowing use of aluminum or copper in the conductors.

### RELATED APPLICATION

This application is related to Herner et al., U.S. application Ser. No. ______, “High-Density Nonvolatile Memory Array Fabricated at Low Temperature Comprising Semiconductor Diodes,” (attorney docket number MA-145), hereinafter the ______ application, which is assigned to the assignee of the present invention, filed on even date herewith and hereby incorporated by reference in its entirety.

### BACKGROUND OF THE INVENTION

The invention relates to a rewriteable nonvolatile memory array in which each cell comprises a diode and a resistance-switching element in series.

Resistance-switching materials, which can reversibly be converted between a high-resistance state and a low-resistance state, are known. These two stable resistance states make such materials an attractive option for use in a rewriteable non-volatile memory array. It is very difficult to form a large, high-density array of such cells, however, due to the danger of disturbance between cells, high leakage currents, and myriad fabrication challenges.

There is a need, therefore, for a large rewriteable nonvolatile memory array using resistance-switching elements which can be readily fabricated and reliably programmed.

### SUMMARY OF THE PREFERRED EMBODIMENTS

The present invention is defined by the following claims, and nothing in this section should be taken as a limitation on those claims. In general, the invention is directed to a nonvolatile memory cell comprising a diode and a resistance-switching material.

A first aspect of the invention provides for a nonvolatile memory cell comprising: a diode; and a reversible resistance-switching element comprising a resistance-switching metal oxide or nitride, the metal oxide or nitride including only one metal.

A preferred embodiment of the invention provides for a plurality of nonvolatile memory cells comprising: a first plurality of substantially parallel, substantially coplanar conductors extending in a first direction; a first plurality of diodes; a first plurality of reversible resistance-switching elements; and a second plurality of substantially parallel, substantially coplanar conductors extending in a second direction different from the first direction, wherein, in each memory cell, one of the first diodes and one of the first reversible resistance-switching elements are arranged in series, disposed between one of the first conductors and one of the second conductors, and wherein the first plurality of reversible resistance-switching elements comprise a material selected from the group consisting of NiO, Nb₂O₅, TiO₂, HfO₂, Al₂O₃, MgOₓ, CrO₂, VO, BN, and AlN.

Another aspect of the invention provides for a monolithic three dimensional memory array comprising: a) a first memory level formed above a substrate, the first memory level comprising: a first plurality of memory cells, wherein each memory cell of the first memory comprises a reversible resistance-switching element comprising a resistance-switching metal oxide or nitride, the metal oxide or nitride having only one metal; and b) at least a second memory level monolithically formed above the first memory level.

Yet another aspect of the invention provides for a method for forming a plurality of nonvolatile memory cells, the method comprising the following steps: forming a first plurality of substantially parallel, substantially coplanar conductors; forming a first plurality of diodes above the first conductors; forming a first plurality of reversible resistance-switching elements; and forming a second plurality of substantially parallel, substantially coplanar conductors above the first diodes, wherein the first reversible resistance-switching elements comprise a material selected from the group consisting of NiO, Nb₂O₅, TiO₂, HfO₂, Al₂O₃, MgOₓ, CrO₂, VO, BN, and AlN.

A related aspect of the invention provides for a method for forming a monolithic three dimensional memory array, the method comprising the following steps: a) forming a first memory level above a substrate, the first memory level formed by a method comprising: i) forming a first plurality of diodes; and ii) forming a first plurality of reversible resistance-switching elements comprising material selected from the group consisting of NiO, Nb₂O₅, TiO₂, HfO₂, Al₂O₃, MgOₓ, CrO₂, VO, BN, and AlN, wherein each of the first diodes is arranged in series with one of the resistance-switching elements; and b) monolithically forming at least a second memory level above the first memory level and above the substrate.

Another preferred embodiment of the invention provides for a method for forming a monolithic three dimensional memory array, the method comprising the following steps: forming a first plurality of substantially parallel, substantially coplanar conductors at a first height above a substrate and extending in a first direction; forming a second plurality of substantially parallel, substantially coplanar conductors at a second height above the first height and extending in a second direction different from the first direction; forming a first plurality of reversible resistance-switching elements comprising a material selected from the group consisting of NiO, Nb₂O₅, TiO₂, HfO₂, Al₂O₃, MgOₓ, CrO₂, VO, BN, and AlN; forming a first plurality of diodes, wherein the first diodes and the first resistance switching elements are above the first height and below the second height; forming second diodes above the second conductors; and forming third conductors above the second conductors.

Another aspect of the invention provides for a method for forming a nonvolatile memory cell, the method comprising: forming a first conductor; forming a second conductor; forming a reversible resistance-switching element; and forming a diode, wherein the diode and the reversible resistance-switching element are disposed electrically in series between the first conductor and the second conductor, and wherein, during formation of the first and second conductors, diode, and switching element and crystallization of the diode, temperature does not exceed about 500 degrees C.

Another aspect of the invention provides for a method for forming a monolithic three dimensional memory array, the method comprising: i) forming a first memory level above a substrate, the first memory level comprising a plurality of first memory cells, each first memory cell comprising: a) a reversible resistance-switching element; and b) a diode, wherein the temperature during formation of the first memory level does not exceed about 475 degrees C.; and ii) monolithically forming at least a second memory level about the first memory level.

A preferred aspect of the invention provides for a nonvolatile memory cell comprising: a diode comprising semiconductor material, wherein the semiconductor material diode is germanium or a germanium alloy; and a reversible resistance-switching element.

Another aspect of the invention provides for a monolithic three dimensional memory array comprising: i) a first memory level formed above a substrate, the first memory level comprising a plurality of first memory cells, each first memory cell comprising: a) a reversible resistance-switching element; and b) a diode, the diode comprising a semiconductor material, wherein the semiconductor material is germanium or a germanium alloy; and ii) at least a second memory level monolithically formed above the first memory level.

Yet another aspect of the invention provides for a monolithic three dimensional memory array comprising: i) a first memory level formed above a substrate, the first memory level comprising a plurality of first memory cells, each first memory cell comprising: a first bottom conductor formed above the substrate, the first bottom conductor comprising a layer of aluminum, an aluminum alloy, or copper; a reversible resistance-switching element; and a diode formed above the first bottom conductor; and

ii) at least a second memory level monolithically formed above the first memory level.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a perspective view of a possible memory cell having a resistance-switching material disposed between conductors.

FIG. 2 is a perspective view of a rewriteable nonvolatile memory cell formed according to the present invention.

FIG. 3 is a perspective view of a memory level comprising cells like those shown in FIG. 2.

FIG. 4 is an I-V curve showing the low-to-high and high-to-low resistance conversions of nondirectional resistance-switching material.

FIG. 5a is an I-V curve showing the low-to-high resistance conversion of directional resistance-switching material. FIG. 5b is an I-V curve showing the high-to-low resistance conversion of directional resistance-switching material.

FIG. 6 is a perspective view of a vertically oriented p-i-n diode preferred in some embodiments of the present invention.

FIG. 7 is a perspective view of a vertically oriented Zener diode preferred in other embodiments of the present invention.

FIG. 8 is an I-V curve of a p-i-n diode like the diode of FIG. 6.

FIG. 9 is an I-V curve of a Zener diode like the diode of FIG. 7.

FIG. 10 is a perspective view of an embodiment of the present invention in which the resistance-switching material is sandwiched between noble metal layers.

FIG. 11a is a cross-sectional view illustrating an embodiment of the present invention in which the resistance-switching material is not patterned and etched. FIG. 11b is a perspective view of a preferred embodiment of the present invention in which the resistance-switching material is patterned and etched with the top conductor.

FIGS. 12a-12c are cross-sectional views illustrating stages in the formation of a memory level of a monolithic three dimensional memory array formed according to a preferred embodiment of the present invention.

FIG. 13 is a cross-sectional view illustrating a portion of a monolithic three dimensional memory array formed according to a preferred embodiment of the present invention.

FIG. 14 is a cross-sectional view illustrating a portion of a monolithic three dimensional memory array formed according to a different preferred embodiment of the present invention.

### DETAILED DESCRIPTION OF THE PREFERRED EMBODIMENTS

A variety of materials show reversible resistance-switching behavior. These materials include chalcogenides, carbon polymers, perovskites, and certain metal oxides and nitrides. Specifically, there are metal oxides and nitrides which include only one metal and exhibit reliable resistance switching behavior. This group includes, for example, NiO, Nb₂O₅, TiO₂, HfO₂, Al₂O₃, MgOₓ, CrO₂, VO, BN, and AlN, as described by Pagnia and Sotnick in “Bistable Switching in Electroformed Metal-Insulator-Metal Device,” Phys. Stat. Sol. (A) 108, 11-65 (1988). A layer of one of these materials may be formed in an initial state, for example a relatively low-resistance state. Upon application of sufficient voltage, the material switches to a stable high-resistance state. This resistance switching is reversible; subsequent application of appropriate current or voltage can serve to return the resistance-switching material to a stable low-resistance state. This conversion can be repeated many times. For some materials, the initial state is high-resistance rather than low-resistance. When this discussion refers to “resistance-switching material”, “resistance-switching metal oxide or nitride”, “resistance-switching memory element” or similar terms, it will be understood that a reversible resistance-switching material is meant.

These resistance-switching materials thus are of interest for use in nonvolatile memory arrays. One resistance state may correspond to a data “0”, for example, while the other resistance state corresponds to a data “1”. Some of these materials may have more than two stable resistance states.

To make a memory cell using these materials, the difference in resistivity between the high-resistivity state and the low-resistivity state must be large enough to be readily detectable. For example, the resistivity of the material in the high-resistivity state should be at least three times that of the material in the low-resistivity state. When this discussion refers to “resistance-switching material”, “resistance-switching metal oxide or nitride”, “resistance-switching memory element” or similar terms, it will be understood that the difference between the low- and high-resistance or low- or high-resistivity states is at least a factor of three.

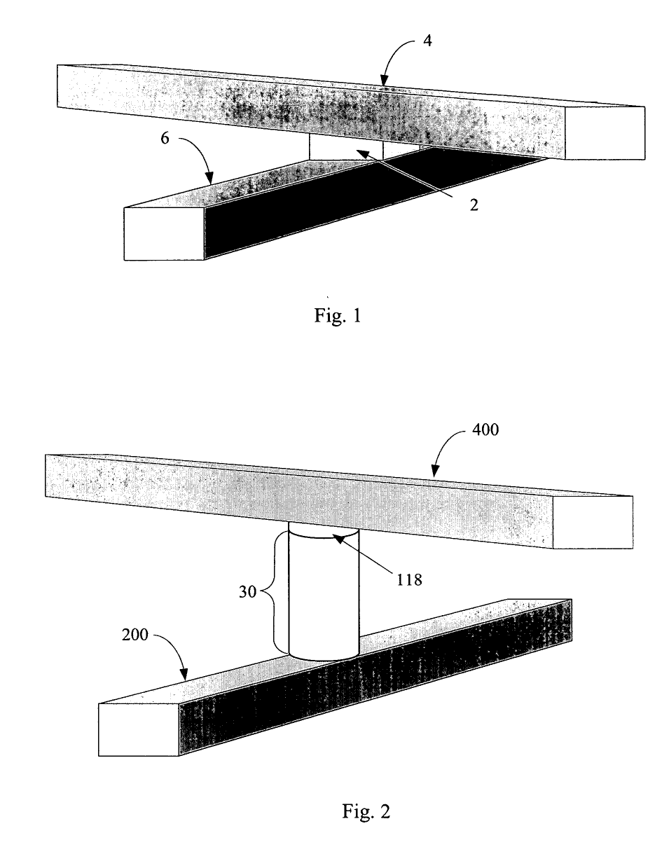

Many obstacles exist to using these resistance-switching materials in a large nonvolatile memory array, however. In one possible arrangement a plurality of memory cells are formed, each as shown in FIG. 1, comprising a resistance-switching memory element 2 (comprising one of the resistance-switching materials named), disposed between conductors, for example between a top conductor 4 and a bottom conductor 6, in a cross-point array. A resistance-switching memory element 2 is programmed by applying voltage between the top conductor 4 and bottom conductor 6.

In a large array of such cells arranged in a cross-point array, however, and when relatively large voltage or current is required, there is danger that memory cells that share the top or the bottom conductor with the cell to be addressed will be exposed to sufficient voltage or current to cause undesired resistance switching in those half-selected cells. Depending on the biasing scheme used, excessive leakage current across unselected cells may also be a concern.

In the present invention, a diode is paired with a resistance-switching material to form a rewriteable nonvolatile memory cell that can be formed and programmed in a large, high-density array. Using the methods described herein, such an array can be reliably fabricated and programmed.

Though many embodiments are possible and an illustrative selection will be described, a simple version of a memory cell formed according to the present invention is shown in FIG. 2. The cell includes a bottom conductor 200 comprising conductive material, for example heavily doped semiconductor material, conductive suicides, or preferably a metal, for example tungsten, aluminum, or copper. Formed above this is a top conductor 400, which may be of the same material as the bottom conductor. The rail-shaped top and bottom conductors preferably extend in different directions; for example they may be perpendicular. The conductors may include conductive barrier or adhesion layers as required. Aluminum conductors may have an antireflective coating to facilitate patterning by photolithography. Disposed between the top conductor 400 and bottom conductor 200 are a diode 30 and a resistance-switching element 118 arranged in series. Other layers, for example barrier layers, may also be included between conductors 200 and 400. The resistance-switching element 118 is converted from the low-resistance state to the high-resistance state, or, alternatively, from the high-resistance state to the low-resistance state, upon application of voltage across or flow of current through the resistance-switching element 118. The conversion from low resistance to high resistance is reversible.

The diode 30 acts as a one-way valve, conducting current more easily in one direction than in the other. Below a critical “turn-on” voltage in the forward direction, the diode 30 conducts little or no current. By use of appropriate biasing schemes, when an individual cell is selected for programming, the diodes of neighboring cells can serve to electrically isolate the resistance-switching elements of those cells and thus prevent inadvertent programming, so long as the voltage across unselected or half-selected cells does not exceed the turn-on voltage of the diode when applied in the forward direction, or the reverse breakdown voltage when applied in the reverse direction.

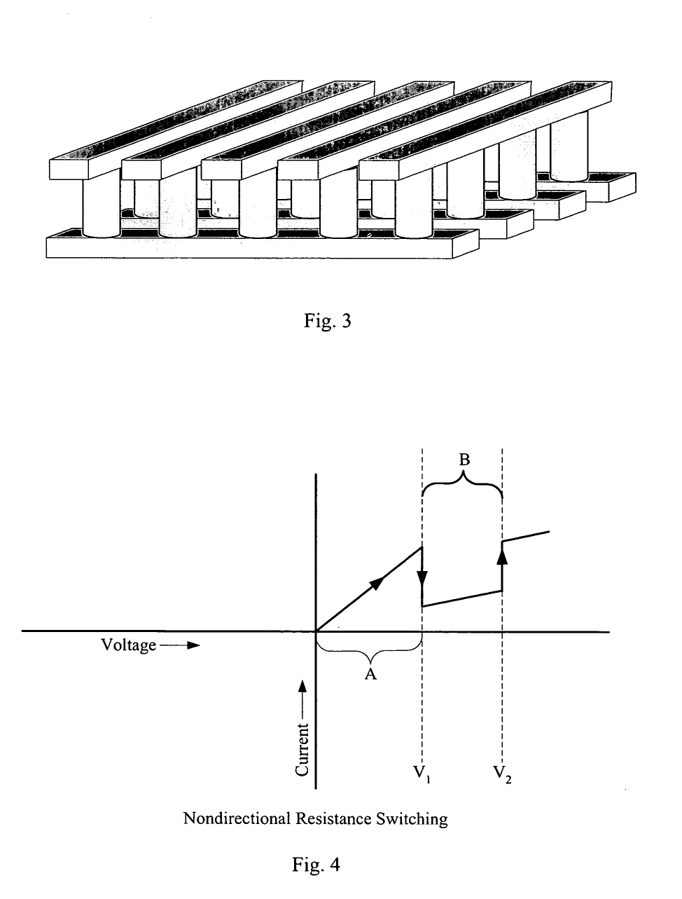

A plurality of such top and bottom conductors, with intervening diodes and resistance-switching elements, can be fabricated, forming a first memory level, a portion of which is shown in FIG. 3. In preferred embodiments, additional memory levels can be formed stacked above this first memory level, forming a highly dense monolithic three dimensional memory array. The memory array is formed of deposited and grown layers above a substrate, for example a monocrystalline silicon substrate. Support circuitry is advantageously formed in the substrate below the memory array.

An advantageous method for making a dense nonvolatile one-time programmable memory array which is reliably manufacturable is taught in Herner et al., U.S. application Ser. No. 10/326,470, hereinafter the '470 application, since abandoned, and hereby incorporated by reference. Related memory arrays, and their use and methods of manufacture, are taught in Herner et al., U.S. patent application Ser. No. 10/955,549, “Nonvolatile Memory Cell Without a Dielectric Antifuse Having High- and Low-Impedance States,” filed Sep. 29, 2004 and hereinafter the '549 application; in Herner et al., U.S. patent application Ser. No. 11/015,824, “Nonvolatile Memory Cell Comprising a Reduced Height Vertical Diode,” filed Dec. 17, 2004, and hereinafter the '824 application; and in Herner et al., U.S. patent application Ser. No. 10/954,577, “Junction Diode Comprising Varying Semiconductor Compositions,” filed Sep. 29, 2004, and hereinafter the '577 application, all owned by the assignee of the present application and hereby incorporated by reference. Methods taught in these incorporated applications will be useful in fabricating a memory array according to the present invention.

Resistance-Switching Material Properties and Preferred Embodiments

Preferred embodiments include several important variations. In general, the properties of the resistance-switching material selected will determine which embodiments are most advantageous.

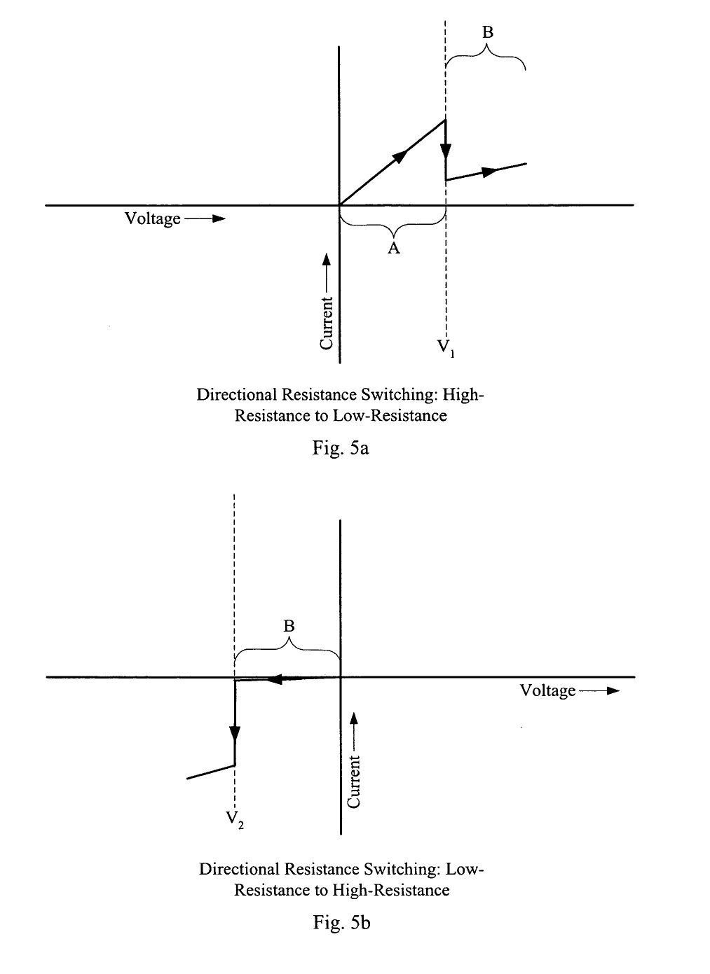

Nondirectional vs. Directional Switching: In general, the resistance-switching metal oxides and nitrides named earlier exhibit one of two general kinds of switching behavior. Referring to the I-V curve of FIG. 4, some of these materials, such as NiO, are initially in a low-resistance state, in area A on the graph. Current flows readily for applied voltage until a first voltage V₁ is reached. At voltage V₁ the resistance-switching material converts to a high-resistance state, shown in area B, and reduced current flows. At a certain critical higher voltage V₂, the material switches back to the initial low-resistance state, and increased current flows. Arrows indicate the order of state changes. This conversion is repeatable. For these materials, the direction of current flow and of voltage bias is immaterial; thus these materials will be referred to as nondirectional. Voltage V₁ may be called the reset voltage while voltage V₂ may be called the set voltage.

Others of the resistance-switching materials, on the other hand, behave as shown in FIGS. 5a and 5b, and will be called directional. Directional resistance-switching materials may also be formed in a low-resistance state, shown in area A of FIG. 5a. Current flows readily for applied voltage until a first voltage V₁, the reset voltage, is reached. At voltage V₁ the directional resistance-switching material converts to a high-resistance state, shown in area B in FIG. 5a. To convert directional resistance-switching material back to the low-resistance state, however, a reverse voltage must be applied. As shown in FIG. 5b, the directional resistance-switching material is high-resistance in area B at negative voltage until a critical reverse voltage V₂, the set voltage. At this voltage the directional resistance switching material reverts to the low-resistance state. Arrows indicate the order of state changes. (Some materials are initially formed in a high-resistance state. The switching behavior is the same; for simplicity only one initial state has been described.)

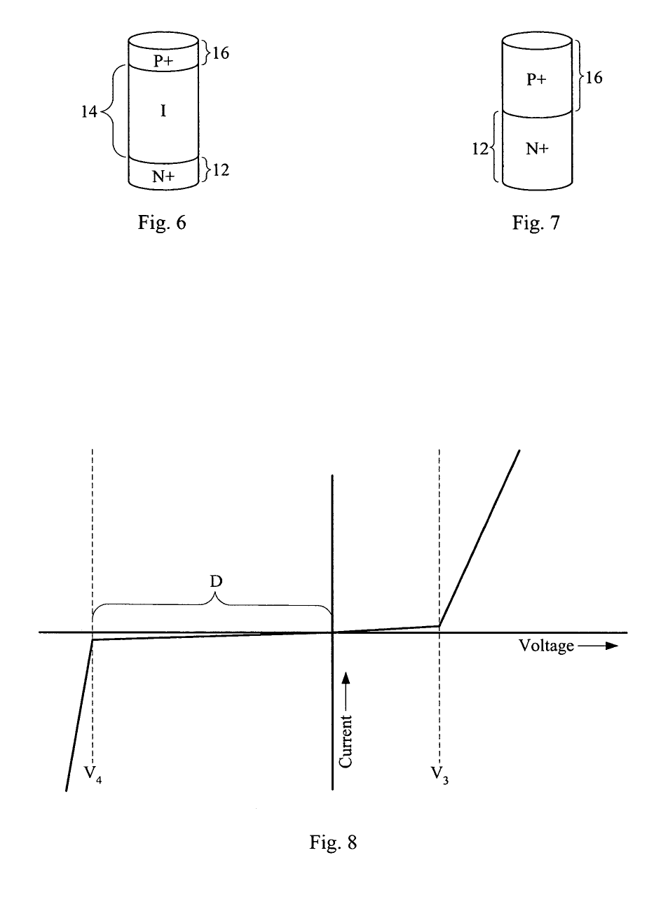

In preferred embodiments, nondirectional resistance-switching materials may be paired with a substantially one-directional diode. One such diode is a p-i-n diode, shown in FIG. 6. A preferred p-i-n diode is formed of semiconductor material, for example silicon, and includes a bottom heavily doped region 12 having a first conductivity type, a middle intrinsic region 14 which is not intentionally doped, and a top heavily doped region 16 having a second conductivity type opposite the first. In the p-i-n diode of FIG. 6, bottom region 12 is n-type while top region 16 is p-type; if desired the polarity can be reversed. A region of intrinsic semiconductor material like region 14, while not intentionally doped, will never be perfectly electrically neutral. In many fabrication processes, defects in intrinsic deposited silicon cause this material to behave as though slightly n-type. In some embodiments, it may be preferred to lightly dope this region. Upon application of voltage, such a diode behaves as shown by the I-V curve of FIG. 8. Little or no current flows at very low voltage. At a critical voltage V₃, the turn-on voltage of the diode, the diode begins to conduct and significant forward current flows. When the diode is placed under low and moderate reverse voltages, as in area D of FIG. 7, little or no current flows; the diode acts as a one-way valve.

Upon application of very high reverse voltage V₄, however, the diode will suffer avalanche breakdown and a reverse current will begin to flow. This event is generally destructive to the diode. Recall that both the set and reset voltages of a nondirectional resistance switching material require current in only one direction. Thus the p-i-n diode of FIG. 6 can successfully be paired with a nondirectional resistance-switching material.

As illustrated in the I-V curve of FIGS. 5a and 5b, however, for successful switching, directional resistance-switching materials must be exposed to both forward and reverse current. The low-resistance to high-resistance conversion shown in FIG. 5b requires reverse current (at voltage V₂.) Reverse current is only achieved in a one-way diode at the reverse breakdown voltage (voltage V₄ in FIG. 8), which is generally relative high, for example at least 10 volts.

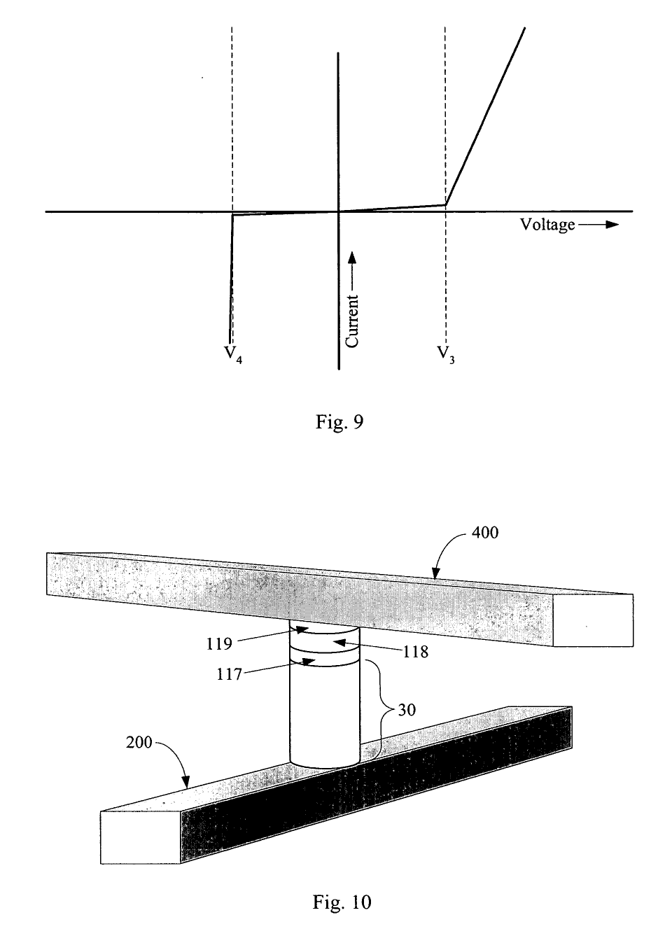

Directional resistance-switching materials thus are not advantageously paired with a one-way diode. Instead such materials may be paired with a reversible non-ohmic device, i.e. one that allows current flow in either direction. One such device is a Zener diode. An examplary Zener diode is shown in FIG. 7. It will be seen that such a diode has a first heavily doped region 12 of a first conductivity type and a second heavily doped region 16 of the opposite conductivity type. The polarity could be reversed. There is no intrinsic region in the Zener diode of FIG. 7; in some embodiments there may be a very thin intrinsic region. FIG. 9 shows an I-V curve of a Zener diode. The Zener diode behaves like a p-i-n diode under forward bias, with turn-on voltage V₃. Under reverse bias, however, once a critical voltage V₄ is reached, the Zener diode will allow a reverse current to flow. In a Zener diode the critical reverse voltage V₄ is substantially lower in magnitude than that of a one-way diode. Such a controllable reverse current at moderate voltage is required to convert directional resistance-switching material from the high-resistance to the low-resistance state, as described earlier and shown in FIG. 5b (at voltage V₂). Thus in embodiments of the present invention using directional resistance-switching material, a Zener diode is preferred.

Nondirectional materials don't require current in both the forward and the reverse direction, but, as described, resistance-switching can be achieved in either direction. For some circuit arrangements, then, it may be advantageous to pair a nondirectional resistance-switching material with a Zener diode.

The term junction diode is used herein to refer to a semiconductor device with the property of non-ohmic conduction, having two terminal electrodes, and made of semiconducting material which is p-type at one electrode and n-type at the other. Examples include p-n diodes and n-p diodes, which have p-type semiconductor material and n-type semiconductor material in contact, such as Zener diodes, and p-i-n diodes, in which intrinsic (undoped) semiconductor material is interposed between p-type semiconductor material and n-type semiconductor material.

High Current Requirements: To reset the resistance-switching material, causing the transition from the high-resistance to the low-resistance state in nondirectional resistance-switching materials, for some materials a relatively high current may be required. For these materials, it may be preferred for the diode to be germanium or a germanium alloy, which provides higher current at a given voltage compared to silicon.

Noble Metal Contacts and Low Temperature Fabrication: It has been observed that resistance switching of some of the metal oxides and nitrides mentioned earlier is more easily and reliably achieved when the resistance-switching material is sandwiched between noble metal contacts, which may be formed, for example, of Ir, Pt, Pd or Au. An example of a cell according to the present invention in which noble metal contacts are used is shown in FIG. 10. Resistance-switching element 118 is between noble metal layers 117 and 119.

Use of noble metals poses challenges, however. When exposed to high temperature, noble metals tend to diffuse rapidly, and may damage other parts of the device. For example, in FIG. 10, noble metal layer 117 is adjacent to semiconductor diode 30. Extensive diffusion of a noble metal into the semiconductor material of diode 30 will damage device performance. When the resistance-switching element is formed between noble metal contacts, then, it is advantageous to minimize processing temperatures. The diode may be silicon, germanium, or a silicon-germanium alloy. Germanium can be crystallized at lower temperatures than silicon, and as the germanium content of a silicon-germanium alloy increases, the crystallization temperature decreases. Diodes formed of germanium or germanium alloys may be preferred when noble metal contacts are used.

Conventional deposition and crystallization temperatures of polycrystalline silicon (in this discussion polycrystalline silicon will be referred to as polysilicon while polycrystalline germanium will be referred to as polygermanium) are relatively high, rendering use of conventionally formed polysilicon diodes incompatible with certain metals having relatively low melting points. For example, aluminum wires begin to soften and extrude when exposed to temperatures above about 475 degrees C. For this reason, in many of the embodiments of the '470, '549, and '824 applications, it is preferred to use tungsten in the conductors, as tungsten wiring can withstand higher temperatures. If germanium or a germanium alloy is used, however, the lower deposition and crystallization temperatures of germanium may allow the use of aluminum or even copper in the conductors, for example in conductors 200 and 400 of FIG. 10. These metals have low sheet resistance, and thus are generally preferable if the thermal budget allows their use, though tungsten or some other conductive material may be used instead. Any of the teachings of Herner et al., U.S. patent application Ser. No. ______, a related application filed on even date herewith and previously incorporated, which relate to low-temperature fabrication may be applicable when low temperatures are preferred.

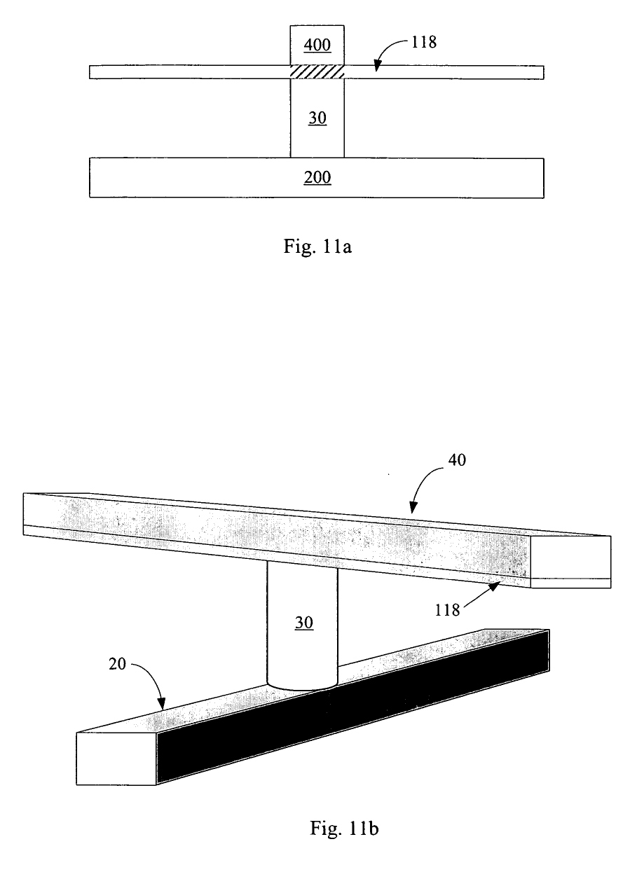

Conductivity and Isolation: It has been described that to enable programming in large arrays, a diode is advantageously included in each memory cell to provide electrical isolation between neighboring cells. Some resistance-switching materials are deposited in a high-resistance state, while others are deposited in a low-resistance state. For a resistance-switching material deposited in a high-resistance state, in general, conversion to a low-resistance state is a localized phenomenon. For example, referring to FIG. 11a, suppose a memory cell (shown in cross-section) includes a rail-shaped bottom conductor 200, extending left to right across the page, a diode 30, a layer 118 of resistance-switching material formed in a high-resistance state, and a rail-shaped top conductor 400 extending out of the page. In this case, the layer 118 of resistance-switching material has been formed as a blanket layer. So long as the high-resistance state of the layer 118 of resistance-switching material is sufficiently high, layer 118 will not provide an undesired conductive path, shorting conductor 400 to adjacent conductors or diode 30 to adjacent diodes. When layer 118 of resistance-switching material is exposed to a high voltage and is converted to a low-resistance state, it is expected that only the areas of layer 118 immediately adjacent to the diode will be converted; for example, after programming, the shaded region of layer 118 will be low-resistance, while the unshaded region will remain high-resistance. The shaded regions are resistance-switching elements disposed within a continuous layer 118 of resistance-switching material.

Depending on the read, set, and reset voltages, however, for some resistance-switching materials, the high-resistance state of the resistance-switching material may be too conductive for reliable isolation, and will tend to short adjacent conductors or diodes when formed in a continuous layer as in FIG. 11a. For different resistance-switching materials, then, it may provide desirable to a) leave the resistance-switching material 118 unpatterned, as in the device of FIG. 11a, or b) pattern the resistance-switching material 118 with the top or bottom conductors, as in the device of FIG. 11b (in perspective view), or c) pattern the resistance-switching material 118 with the diode 30, as in the devices of FIGS. 2 and 10.

When a memory element is formed of a resistance-switching material which is formed in a low-resistance state, it must be isolated from the resistance-switching memory element of adjacent cells to avoid forming an unwanted conductive path between them.

### EXAMPLE

### First Embodiment

A detailed example will be provided of fabrication of a monolithic three dimensional memory array formed according to a preferred embodiment of the present invention. For clarity many details, including steps, materials, and process conditions, will be included. It will be understood that this example is non-limiting, and that these details can be modified, omitted, or augmented while the results fall within the scope of the invention.

In general, the '470 application, the '549 application, the '824 application, and the '577 application teach memory arrays comprising memory cells, wherein each memory cell is a one-time programmable cell. The cell is formed in a high-resistance state, and, upon application of a programming voltage, is permanently converted to a low-resistance state. Specifically, teachings of the '470, '549, '824, '577 and other incorporated applications and patents may be relevant to formation of a memory according to the present invention. For simplicity, not all of the details of the incorporated applications and patents will be included, but it will be understood that no teaching of these applications or patents is intended to be excluded.

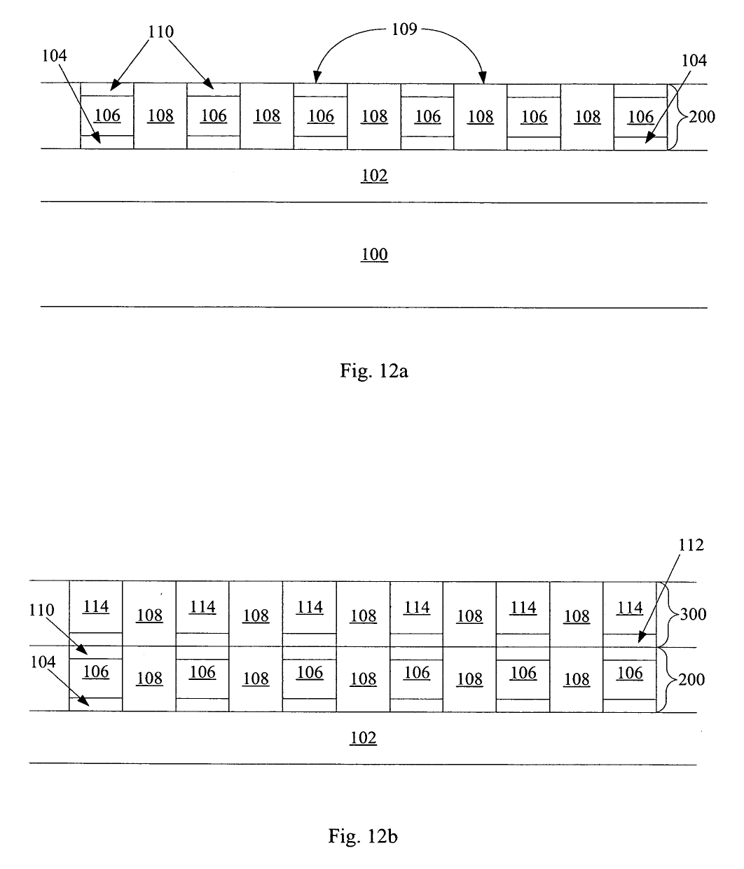

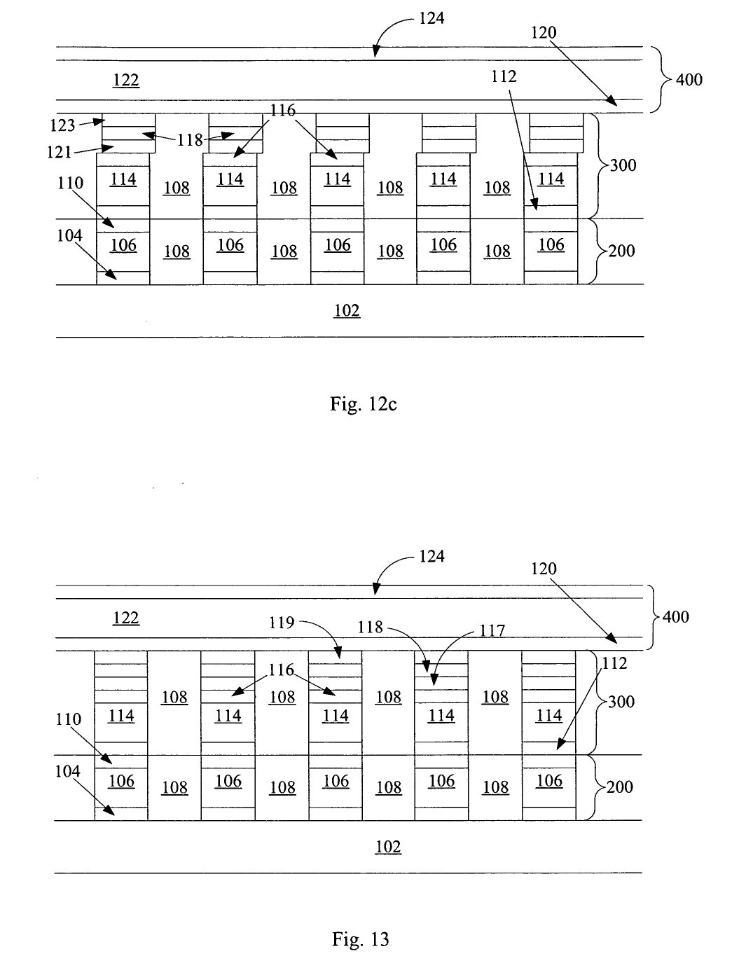

Turning to FIG. 12a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, high-dielectric film, Si—C—O—H film, or any other suitable insulating material.

The first conductors 200 are formed over the substrate 100 and insulator 102. An adhesion layer 104 may be included between the insulating layer 102 and the conducting layer 106 to help the conducting layer 106 adhere. A preferred material for the adhesion layer 104 is titanium nitride, though other materials may be used, or this layer may be omitted. Adhesion layer 104 can be deposited by any conventional method, for example by sputtering.

The thickness of adhesion layer 104 can range from about 20 to about 500 angstroms, and is preferably between about 100 and about 400 angstroms, most preferably about 200 angstroms. Note that in this discussion, “thickness” will denote vertical thickness, measured in a direction perpendicular to substrate 100.

The next layer to be deposited is conducting layer 106. Conducting layer 106 can comprise any conducting material known in the art, such as doped semiconductor, metals such as tungsten, or conductive metal silicides; in a preferred embodiment, conducting layer 106 is aluminum. The thickness of conducting layer 106 can depend, in part, on the desired sheet resistance and therefore can be any thickness that provides the desired sheet resistance. In one embodiment, the thickness of conducting layer 106 can range from about 500 to about 3000 angstroms, preferably about 1000 to about 2000 angstroms, most preferably about 1200 angstroms.

Another layer 110, preferably of titanium nitride, is deposited on conducting layer 106. It may have thickness comparable to that of layer 104. A photolithography step will be performed to pattern aluminum layer 106 and titanium nitride layer 104. The high reflectivity of aluminum makes it difficult to successfully perform photolithography directly on an aluminum layer. Titanium nitride layer 110 serves as an anti-reflective coating.

Once all the layers that will form the conductor rails have been deposited, the layers will be patterned and etched using any suitable masking and etching process to form substantially parallel, substantially coplanar conductors 200, shown in FIG. 12a in cross-section. In one embodiment, photoresist is deposited, patterned by photolithography and the layers etched, and then the photoresist removed, using standard process techniques such as “ashing” in an oxygen-containing plasma, and strip of remaining polymers formed during etch in a conventional liquid solvent such as those formulated by EKC.

Next a dielectric material 108 is deposited over and between conductor rails 200. Dielectric material 108 can be any known electrically insulating material, such as silicon oxide, silicon nitride, or silicon oxynitride. In a preferred embodiment, silicon oxide is used as dielectric material 108. The silicon oxide can be deposited using any known process, such as chemical vapor deposition (CVD), or, for example, high-density plasma CVD (HDPCVD).

Finally, excess dielectric material 108 on top of conductor rails 200 is removed, exposing the tops of conductor rails 200 separated by dielectric material 108, and leaving a substantially planar surface 109. The resulting structure is shown in FIG. 12a. This removal of dielectric overfill to form planar surface 109 can be performed by any process known in the art, such as etchback or chemical mechanical polishing (CMP). For example, the etchback techniques described in Raghuram et al., U.S. application Ser. No. 10/883,417, “Nonselective Unpatterned Etchback to Expose Buried Patterned Features,” filed Jun. 30, 2004 and hereby incorporated by reference in its entirety, can advantageously be used.

In preferred embodiments, then, bottom conductors 200 are formed by depositing a first layer or stack of conductive material; patterning and etching the first layer or stack of conductive material to form first conductors; and depositing dielectric fill between the first conductors.

Alternatively, conductor rails can be formed by a damascene process, in which oxide is deposited, trenches are etched in the oxide, then the trenches are filled with conductive material to create the conductor rails. Formation of conductors 200 using a copper damascene process is described in Herner et al., U.S. patent application Ser. No. ______, filed on even date herewith and previously incorporated. Copper damascene conductors include at least a barrier layer and a copper layer.

Next, turning to FIG. 12b, vertical pillars will be formed above completed conductor rails 200. (To save space substrate 100 is omitted in FIG. 12b and subsequent figures; its presence will be assumed.) Semiconductor material that will be patterned into pillars is deposited. The semiconductor material can be germanium, silicon, silicon-germanium, silicon-germanium-carbon, or other suitable IV-IV compounds, gallium arsenide, indium phosphide, or other suitable III-V compounds, zinc selinide, or other II-VII compounds, or a combination. Silicon-germanium alloys of any proportion of silicon and germanium, for example including at least 20, at least 50, at least 80, or at least 90 atomic percent germanium or pure germanium may be used. The present example will describe the use of pure germanium. The term “pure germanium” does not exclude the presence of conductivity-enhancing dopants or contaminants normally found in a typical production environment.

In preferred embodiments, the semiconductor pillar comprises a junction diode, the junction diode comprising a bottom heavily doped region of a first conductivity type and a top heavily doped region of a second conductivity type. The middle region, between the top and bottom regions, is an intrinsic or lightly doped region of either the first or second conductivity type.

In this example, bottom heavily doped region 112 is heavily doped n-type germanium. In a most preferred embodiment, heavily doped region 112 is deposited and doped with an n-type dopant such as phosphorus by any conventional method, preferably by in situ doping. This layer is preferably between about 200 and about 800 angstroms.

Next the germanium that will form the remainder of the diode is deposited. In some embodiments a subsequent planarization step will remove some germanium, so an extra thickness is deposited. If the planarization step is performed using a conventional CMP method, about 800 angstroms of thickness may be lost (this is an average; the amount varies across the wafer. Depending on the slurry and methods used during CMP, the germanium loss may be more or less.) If the planarization step is performed by an etchback method, only about 400 angstroms of germanium or less may be removed. Depending on the planarization method to be used and the desired final thickness, between about 800 and about 4000 angstroms of undoped germanium is deposited by any conventional method; preferably between about 1500 and about 2500 angstroms; most preferably between about 1800 and about 2200 angstroms. If desired, the germanium can be lightly doped. Top heavily doped region 116 will be formed in a later implant step, but does not exist yet at this point, and thus is not shown in FIG. 12b.

The germanium just deposited will be patterned and etched to form pillars 300. Pillars 300 should have about the same pitch and about the same width as conductors 200 below, such that each pillar 300 is formed on top of a conductor 200. Some misalignment can be tolerated.

The pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask.

The photolithography techniques described in Chen, U.S. application Ser. No. 10/728,436, “Photomask Features with Interior Nonprinting Window Using Alternating Phase Shifting,” filed Dec. 5, 2003; or Chen, U.S. application Ser. No. 10/815,312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

Dielectric material 108 is deposited over and between pillars 300, filling the gaps between them. Dielectric material 108 can be any known electrically insulating material, such as silicon oxide, silicon nitride, or silicon oxynitride. In a preferred embodiment, silicon dioxide is used as the insulating material. The silicon dioxide can be deposited using any known process, such as CVD or HDPCVD.

Next the dielectric material on top of the pillars 300 is removed, exposing the tops of pillars 300 separated by dielectric material 108, and leaving a substantially planar surface. This removal of dielectric overfill and planarization can be performed by any process known in the art, such as CMP or etchback. For example, the etchback techniques described in Raghuram et al. can be used. The resulting structure is shown in FIG. 12b.

Turning to FIG. 12c, in preferred embodiments, heavily doped top regions 116 are formed at this point by ion implantation with a p-type dopant, for example boron or BF₂. The diode described herein has a bottom n-type region and a top p-type region. If preferred, the conductivity types could be reversed. If desired, p-i-n diodes having an n-region on the bottom could be used in one memory level while p-i-n diodes having a p-type region on the bottom could be used in another memory level.

The diodes that reside in pillars 300 were formed by a method comprising depositing a semiconductor layer stack above the first conductors and dielectric fill; and patterning and etching the semiconductor layer stack to form the first diodes.

Next a layer 121 of a conductive barrier material, for example titanium nitride, a metal, or some other appropriate material, is deposited. The thickness of layer 121 may be between about 100 and about 400 angstroms, preferably about 200 angstroms. In some embodiments, layer 121 may be omitted. A layer 118 of a metal oxide or nitride resistance-switching material is deposited on barrier layer 121. This layer is preferably between about 200 and about 400 angstroms. Layer 118 can be any of the materials described earlier, and is preferably formed of a metal oxide or nitride having including exactly one metal which exhibits resistance switching behavior; preferably a material selected from the group consisting of NiO, Nb₂O₅, TiO₂, HfO₂, Al₂O₃, MgOₓ, CrO₂, VO, BN, and AlN. For simplicity this discussion will describe the use of NiO in layer 118. It will be understood, however, that any of the other materials described can be used. NiO exhibits nondirectional switching behavior, and thus has been paired with a p-i-n diode, though a Zener diode could have been used had the circuit arrangement dictated such a choice. As described earlier, had a directional resistance switching material been selected, a Zener diode would have been preferred. In a preferred embodiment, such a Zener diode has no intrinisic region, or has an intrinsic region no thicker than about 350 angstroms.

Finally in preferred embodiments barrier layer 123 is deposited on NiO layer 118. Layer 123 is preferably titanium nitride, though some other appropriate conductive barrier material may be used instead. The purpose of barrier layer 123 is to allow an upcoming planarization step to be performed on barrier layer 123 rather than NiO layer 118. In some embodiments, layer 123 may be omitted.

Layers 123, 118, and 121 are patterned and etched to form short pillars, ideally directly on top of pillars 300 formed in the previous pattern and etch step. Some misalignment may occur, as shown in FIG. 12c, and can be tolerated. The photomask used to pattern pillars 300 may be reused in this patterning step.

In this example, layers 123, 118, and 121 were patterned in a different patterning step than germanium layers 112 and 114 (and 116, formed in a subsequent ion implantation step.) This may be desirable to reduce etch height and to avoid possible contamination by having NiO and metal barrier layers exposed in a chamber devoted to semiconductor etch. In other embodiments, however, it may be preferred to pattern layers 123, 118, 121, 116, 114, and 112 in a single patterning step. In this case the ion implantation of heavily doped germanium layer 116 takes place before the deposition of barrier layer 121.

In some embodiments, barrier layer 121, NiO layer 118, and barrier layer 123 can be formed before (and therefore beneath) diode layers 112, 114, and 116, and may be patterned in the same or in a separate patterning step.

Next a conductive material or stack is deposited to form the top conductors 400. In a preferred embodiment, titanium nitride barrier layer 120 is deposited next, followed by aluminum layer 122 and top titanium nitride barrier layer 124. Top conductors 400 can be patterned and etched as described earlier. In this example in each cell the diode (of layers 112, 114, and 116) and a resistance-switching element (a portion of NiO layer 118) have been formed in series between top conductor 400 and bottom conductor 200. Overlying second conductors 400 will preferably extend in a different direction from first conductors 200, preferably substantially perpendicular to them. The resulting structure, shown in FIG. 12c, is a bottom or first story of memory cells.

In an alternative embodiment, top conductors can comprise copper, and can be formed by a damascene method. A detailed description of fabrication of top copper conductors in a monolithic three dimensional memory array is provided in detail in Herner et al., U.S. patent application Ser. No. ______, a related application filed on even date herewith and previously incorporated

In preferred embodiments, this first story of memory cells is a plurality of nonvolatile memory cells comprising: a first plurality of substantially parallel, substantially coplanar conductors extending in a first direction; a first plurality of diodes; a first plurality of reversible resistance-switching elements; and a second plurality of substantially parallel, substantially coplanar conductors extending in a second direction different from the first direction, wherein, in each memory cell, one of the first diodes and one of the first reversible resistance-switching elements are arranged in series, disposed between one of the first conductors and one of the second conductors, and wherein the first plurality of reversible resistance-switching elements comprise a material selected from the group consisting of NiO, Nb₂O₅, TiO₂, HfO₂, Al₂O₃, MgOₓ, CrO₂, VO, BN, and AlN. The first conductors are formed at a first height and the second conductors are formed at a second height, the second height above the first height.

Additional memory levels can be formed above this first memory level. In some embodiments, conductors can be shared between memory levels; i.e. top conductor 400 would serve as the bottom conductor of the next memory level. In other embodiments, an interlevel dielectric is formed above the first memory level of FIG. 12c, its surface planarized, and construction of a second memory level begins on this planarized interlevel dielectric, with no shared conductors. If top conductors 400 are not shared between memory levels, then no CMP step need be performed on these conductors. In this case, if desired, titanium nitride barrier layer 124 may be replaced with a layer of DARC.

Deposited germanium, when undoped or doped with n-type dopants and deposited at a relatively low temperature, as described, will generally be amorphous. After all of the memory levels have been constructed, a final relatively low-temperature anneal, for example performed at between about 350 and about 470 degrees C., can be performed to crystallize the germanium diodes; in this embodiment the resulting diodes will be formed of polygermanium. Large batches of wafers, for example 100 wafers or more, can be annealed at a time, maintaining adequate throughput.

Vertical interconnects between memory levels and between circuitry in the substrate are preferably formed as tungsten plugs, which can be formed by any conventional method.

Photomasks are used during photolithography to pattern each layer. Certain layers are repeated in each memory level, and the photomasks used to form them may be reused. For example, a photomask defining the pillars 300 of FIG. 12c may be reused for each memory level. Each photomask includes reference marks used to properly align it. When a photomask is reused, reference marks formed in a second or subsequent use may interfere with the same reference marks formed during a prior use of the same photomask. Chen et al., U.S. patent application Ser. No. 11/097,496, “Masking of Repeated Overlay and Alignment Marks to Allow Reuse of Photomasks in a Vertical Structure,” filed Mar. 31, 2005, and hereby incorporated by reference, describes a method to avoid such interference during the formation of a monolithic three dimensional memory array like that of the present invention.

Many variations on the steps and structures described here can be envisioned and may be desirable. To more fully illustrate the present invention, a few variations will be described; it will be understood that not every variation that falls within the scope of the invention need be fully detailed for those skilled in the art to understand how to make and use a still broader range of possible variations.

### Second Embodiment: Noble Metal Contacts, Above Diode

FIG. 10 showed an embodiment in which resistance-switching material 118 was sandwiched between noble metal layers 117 and 119. Preferred noble metals are Pt, Pd, Ir and Au. Layers 117 and 119 may be formed of the same noble metal, or of different metals.

When the resistance switching material is sandwiched between noble metal layers, the noble metal layers must be patterned and etched to assure that they do not provide unwanted conductive paths between adjacent diodes or conductors.

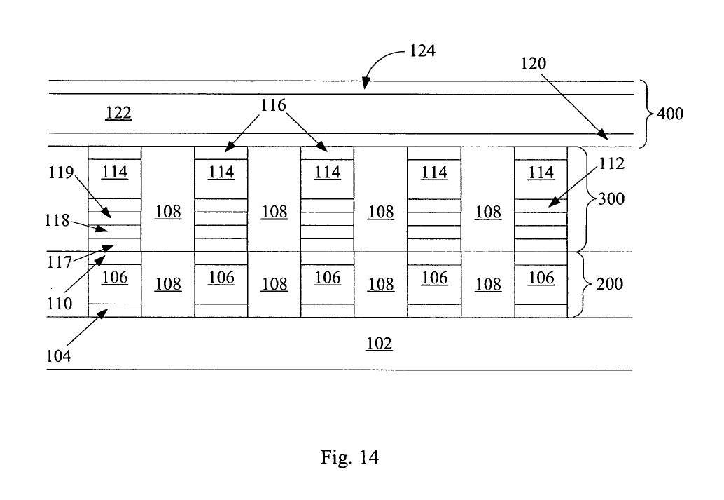

A memory level comprising cells like those of FIG. 10 is shown in cross-section in FIG. 13. In a preferred method to form this structure, bottom conductor 200 is formed as described earlier. Heavily doped germanium layer 112 and undoped germanium layer 114 are deposited as described earlier. In one preferred embodiment, the ion implantation of top heavily doped layer 116 can be performed on the blanket germanium layer before the pillars are patterned and etched. Next noble metal layer 117 is deposited, followed by resistance-switching material 118 and noble metal layer 119. Noble metal layers 117 and 119 may be about 200 to about 500 angstroms, preferably about 200 angstroms.

The pillars are patterned and etched at this point, such that layers 117, 118, and 119 are included in the pillar, and thus are electrically isolated from each other. Depending on the etchants selected, it may be preferred to perform a first etch step, etching only layers 119, 118, and 117, then use these layers as a hard mask to etch the rest of the pillar.

Alternatively, layers 112, 114, and 116 may be patterned and etched, gaps between them filled, and tops of the pillars exposed through planarization first. Deposition of layers 117, 118, and 119 could follow, along with separate pattern and etch of those layers.

The gaps are filled and a CMP or etchback step performed as described earlier to create a substantially planar surface. Next top conductors 400 are formed on this planar surface as described earlier, comprising a titanium nitride layer 120, aluminum layer 122, and titanium nitride layer 124. Alternatively, top noble metal layer 119 could be deposited, patterned and etched with top conductors 400.

In another alternative, heavily doped layer 116 could be doped by in-situ doping rather than by ion implantation.

### Third Embodiment: Noble Metal Contacts, Below Diode

In an alternative embodiment, shown in FIG. 14, the resistance-switching elements 118, in this case sandwiched between noble metal layers 117 and 119, are formed below the diode, rather than above it.

To form this structure, bottom conductors 200 are formed as described earlier. Layers 117, 118, and 119 are deposited on the planarized surface 109 of conductors 200 separated by gap fill. The germanium stack, including heavily doped layer 112 and undoped layer 114, are deposited. Layers 114, 112, 119, 118, and optionally 117 are patterned and etched as described earlier to form pillars 300. After gap fill and planarization, top heavily doped region 116 is formed by ion implantation. Top conductors 400 are formed as in the previous embodiment, by depositing conductive layers, for example titanium nitride layer 120, aluminum layer 122, and titanium nitride layer 124, and patterning and etching to form the conductors 400.

As in other embodiments, if desired, layers 117, 118, and 119 could be patterned and etched separately from layers 112, 114, and 116 instead.

In the preferred embodiments just described, what has been formed is a monolithic three dimensional memory array comprising: a) a first memory level formed above a substrate, the first memory level comprising: a first plurality of memory cells, wherein each memory cell of the first memory comprises a reversible resistance-switching element comprising a material selected from the group consisting of NiO, Nb₂O₅, TiO₂, HfO₂, Al₂O₃, MgOₓ, CrO₂, VO, BN, and AlN; and b) at least a second memory level monolithically formed above the first memory level.

Many other alternative embodiments can be imagined. For example, in some embodiments the noble metal layers 117 and 119 can be omitted. In this case resistance-switching material 118 can be patterned with bottom conductors 200, with pillars 300, or left as a continuous layer above or below the diodes.

An advantage of the embodiments just described is that use of germanium in the diode allows formation of a nonvolatile memory cell by forming a first conductor; forming a second conductor; forming a reversible resistance-switching element; and forming a diode, wherein the diode and the reversible resistance-switching element are disposed electrically in series between the first conductor and the second conductor, and wherein, during formation of the first and second conductors, diode, and switching element and crystallization of the diode, temperature does not exceed about 500 degrees C. Depending on the deposition and crystallization conditions used (a longer crystallizing anneal can be performed at lower temperatures), the temperature may not exceed about 350 degrees C. In alternative embodiments, the deposition and crystallization temperatures of the semiconductor material may be arranged so that the maximum temperature does not exceed 475, 425, 400, or 375 degrees C.

### Programming

As described in detail in the '549 application, for a polycrystalline semiconductor diode formed according to the methods detailed herein, it may be expected that in some embodiments the semiconductor diode will be formed in an initial high-resistance state, and, upon application of a sufficiently high voltage, will be permanently converted to a low-resistance state. Thus, referring to the cell of FIG. 2, when this cell is initially formed, both the diode 30 and the reversible resistance-switching element 118 are formed in a high-resistance state.

Upon first application of a programming voltage, both the diode 30 and the resistance-switching element 118 will be converted to their low-resistance states. The conversion of the diode 30 is permanent, while the conversion of resistance-switching element 118 is reversible. It may be desirable to perform the initial conversion of the diodes from high-resistance to low-resistance in factory conditions, effectively “preconditioning” the diode.

Alternatively, Herner, U.S. patent application Ser. No. 10/954,510, “Memory Cell Comprising a Semiconductor Junction Diode Crystallized Adjacent to a Silicide,” filed Sep. 29, 2004, hereinafter the '510 application, which is assigned to the assignee of the present invention and hereby incorporated by reference, describes a method to form a polycrystalline semiconductor diode which is in a low-resistance state as formed. In preferred embodiments of the '510 application, the semiconductor material of the diode, generally silicon, is crystallized adjacent to a silicide layer, for example TiSi₂. The silicide layer provides an orderly crystallization template for the silicon as it crystallizes, resulting in a highly crystalline diode as formed, with fewer crystalline defects. This technique could be used in the present invention, so that the germanium diode is crystallized adjacent to a germanide layer, such as TiGe₂, which will provide an analogous crystallization template for the germanium. Such a germanium diode will be a low-resistance as formed, with no need for a “programming” step to create a low-resistance path through it.

One-time programmable monolithic three dimensional memory arrays are described in Johnson et al., U.S. Pat. No. 6,034,882, “Vertically Stacked Field Programmable Nonvolatile Memory and Method of Fabrication”; in Knall et al., U.S. Pat. No. 6,420,215, “Three Dimensional Memory Array and Method of Fabrication”; and in Vyvoda et al., U.S. patent application Ser. No. 10/185,507, “Electrically Isolated Pillars in Active Devices,” filed Jun. 27, 2002, all assigned to the assignee of the present invention and hereby incorporated by reference.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A nonvolatile memory cell comprising:
a diode; and
a reversible resistance-switching element comprising a resistance-switching metal oxide or nitride, the metal oxide or nitride including only one metal.

2. The nonvolatile memory cell of claim 1 wherein the metal oxide or nitride is selected from the group consisting of NiO, Nb₂O₅, TiO₂, HfO₂, Al₂O₃, MgOₓ, CrO₂, VO, BN, and AlN.

3. The nonvolatile memory cell of claim 1 wherein the diode and the resistance-switching element are connected in series.

4. The nonvolatile memory cell of claim 3 wherein the diode and the resistance-switching element are disposed between a first conductor and a second conductor.

5. The nonvolatile memory cell of claim 4 wherein the second conductor is above the first conductor, and the diode and the resistance-switching element are vertically disposed between them.

6. The nonvolatile memory cell of claim 5 wherein the diode is above the resistance-switching element.

7. The nonvolatile memory cell of claim 5 wherein the resistance-switching element is above the diode.

8. The nonvolatile memory cell of claim 5 further comprising a pillar, wherein the diode resides in the pillar and is vertically oriented.

9. The nonvolatile memory cell of claim 8 wherein the first conductor and the second conductor are rail-shaped.

10. The nonvolatile memory cell of claim 9 wherein the first conductor extends in a first direction and the second conductor extends in a second direction different from the first direction.

11. The nonvolatile memory cell of claim 10 wherein the resistance-switching element is disposed in the pillar.

12. The nonvolatile memory cell of claim 10 wherein the resistance-switching element is rail-shaped, is disposed between the top conductor and the diode, and extends in the second direction.

13. The nonvolatile memory cell of claim 10 wherein the resistance-switching element is rail-shaped, is disposed between the bottom conductor and the diode, and extends in the first direction.

14. The nonvolatile memory cell of claim 8 wherein the top conductor or the bottom conductor comprises aluminum.

15. The nonvolatile memory cell of claim 8 wherein the top conductor or the bottom conductor comprises tungsten.

16. The nonvolatile memory cell of claim 3 wherein the diode is a semiconductor junction diode.

17. The nonvolatile memory cell of claim 16 wherein the semiconductor junction diode comprises germanium and/or silicon.

18. The nonvolatile memory cell of claim 17 wherein the germanium and/or silicon is not monocrystalline.

19. The nonvolatile memory cell of claim 18 wherein the germanium and/or silicon is polycrystalline.

20. The nonvolatile memory cell of claim 17 wherein the semiconductor junction diode is vertically oriented, comprising a bottom heavily doped region having a first conductivity type, a middle intrinsic or lightly doped region, and a top heavily doped region having a second conductivity type.

21. The nonvolatile memory cell of claim 17 wherein the semiconductor junction diode is a Zener diode.

22. The nonvolatile memory cell of claim 21 wherein the Zener diode is vertically oriented, comprising a bottom heavily doped region having a first conductivity type and a top heavily doped region having a second conductivity type.

23. The nonvolatile memory cell of claim 3 wherein the memory cell is part of a first memory level.

24. The nonvolatile memory cell of claim 23 wherein the first memory level is formed above a monocrystalline silicon substrate.

25. The nonvolatile memory cell of claim 23 wherein at least a second memory level is monolithically formed above the first in a monolithic three dimensional memory array.

26. The nonvolatile memory cell of claim 1 wherein the resistance-switching element is adjacent to a noble metal.

27. The nonvolatile memory cell of claim 26 wherein the noble metal is selected from the group consisting of Pt, Pd, Ir, and Au.

28. The nonvolatile memory cell of claim 3 wherein the resistance-switching element can be in either a high-resistance state or a low-resistance state.

29. The nonvolatile memory cell of claim 28 wherein the resistance-switching element is converted from the high-resistance state to the low-resistance state, or, alternatively, from the low-resistance state to the high-resistance state, upon application of voltage across or flow of current through the resistance-switching element.

30. The nonvolatile memory cell of claim 1 wherein the memory cell is rewriteable.

31. The nonvolatile memory cell of claim 1 wherein the resistance-switching element can be in either a high-resistance state or a low-resistance state.

32. The nonvolatile memory cell of claim 31 wherein, in the high-resistance state, the metal oxide or nitride has a first resistivity, wherein in the low-resistance state, the metal oxide or nitride has a second resistivity, wherein the first resistivity is at least three times the second resistivity.

33. A plurality of nonvolatile memory cells comprising:
a first plurality of substantially parallel, substantially coplanar conductors extending in a first direction;
a first plurality of diodes;
a first plurality of reversible resistance-switching elements; and
a second plurality of substantially parallel, substantially coplanar conductors extending in a second direction different from the first direction,
wherein, in each memory cell, one of the first diodes and one of the first reversible resistance-switching elements are arranged in series, disposed between one of the first conductors and one of the second conductors, and
wherein the first plurality of reversible resistance-switching elements comprise a material selected from the group consisting of NiO, Nb₂O₅, TiO₂, HfO₂, Al₂O₃, MgOₓ, CrO₂, VO, BN, and AlN.

34. The plurality of nonvolatile memory cells of claim 33 wherein the first conductors are formed at a first height and the second conductors are formed at a second height, the second height above the first height.

35. The plurality of nonvolatile memory cells of claim 34 wherein the first diodes are vertically oriented semiconductor junction diodes.

36. The plurality of nonvolatile memory cells of claim 35 wherein the first diodes are p-i-n diodes.

37. The plurality of nonvolatile memory cells of claim 35 wherein the first diodes are Zener diodes.

38. The plurality of nonvolatile memory cells of claim 35 further comprising a first plurality of pillars, each pillar disposed between one of the first conductors and one of the second conductors.

39. The plurality of nonvolatile memory cells of claim 38 wherein each of the first diodes is disposed in one of the first pillars.

40. The plurality of nonvolatile memory cells of claim 39 wherein each of the first resistance-switching elements is disposed in one of the first pillars.

41. The plurality of nonvolatile memory cells of claim 39 wherein each of the first resistance-switching elements is not disposed in one of the first pillars.

42. The plurality of nonvolatile memory cells of claim 33 wherein each of the first resistance-switching elements is sandwiched between layers of noble metal.

43. The plurality of nonvolatile memory cells of claim 42 wherein the noble metal is selected from the group consisting of Pt, Pd, Ir, and Au.

44. A monolithic three dimensional memory array comprising:
a) a first memory level formed above a substrate, the first memory level comprising:
a first plurality of memory cells, wherein each memory cell of the first memory comprises a reversible resistance-switching element comprising a resistance-switching metal oxide or nitride, the metal oxide or nitride having only one metal; and
b) at least a second memory level monolithically formed above the first memory level.

45. The monolithic three dimensional memory array of claim 44 wherein the metal oxide or nitride is selected from the group consisting of NiO, Nb₂O₅, TiO₂, HfO₂, Al₂O₃, MgOₓ, CrO₂, VO, BN, and AlN.

46. The monolithic three dimensional memory array of claim 44 wherein the first memory cells are rewriteable memory cells.

47. The monolithic three dimensional memory array of claim 44 wherein the substrate comprises monocrystalline silicon.

48. The monolithic three dimensional memory array of claim 44 wherein the first memory level further comprises a first plurality of diodes, wherein each memory cell of the first memory level comprises one of the first diodes.

49. The monolithic three dimensional memory array of claim 48 wherein, in each memory cell of the first memory level, the diode and the resistance-switching element are arranged in series.

50. The monolithic three dimensional memory array of claim 49 wherein the first memory level further comprises:
a first plurality of substantially parallel, substantially coplanar bottom conductors extending in a first direction; and
a second plurality of substantially parallel, substantially coplanar conductors extending in a second direction different from the first direction, the second conductors above the first conductors,
wherein, in each memory cell of the first memory level, the first diode and the resistance switching element are disposed between one of the first conductors and one of the second conductors.

51. The monolithic three dimensional memory array of claim 50 wherein the first memory level further comprises a first plurality of pillars, wherein each first pillar is vertically disposed between one of the first conductors and one of the second conductors.

52. The monolithic three dimensional memory array of claim 50 wherein the first conductors or the second conductors comprise tungsten.

53. The monolithic three dimensional memory array of claim 50 wherein the first conductors or the second conductors comprise aluminum.

54. The monolithic three dimensional memory array of claim 50 wherein the first diodes are semiconductor junction diodes.

55. The monolithic three dimensional memory array of claim 54 wherein the first diodes comprise germanium, silicon, or an alloy of germanium and/or silicon.

56. The monolithic three dimensional memory array of claim 55 wherein the first diodes consist essentially of germanium or a semiconductor alloy which is at least 80 atomic percent germanium.

57. The monolithic three dimensional memory array of claim 56 wherein the semiconductor alloy is at least 90 atomic percent germanium.

58. The monolithic three dimensional memory array of claim 49 wherein the first memory level further comprises a continuous layer of resistance-switching material, wherein each of the resistance-switching elements is disposed within the continuous layer of resistance-switching material.

59. The monolithic three-dimensional memory array of claim 58 wherein the continuous layer of resistance-switching material is above the first diodes.

60. The monolithic three-dimensional memory array of claim 58 wherein the continuous layer of resistance-switching material is below the first diodes.

61. The monolithic three dimensional memory array of claim 44 wherein the second memory level comprises a second plurality of memory cells, wherein each memory cell of the second memory level comprises a resistance-switching element comprising a material selected from the group consisting of NiO, Nb₂O₅, TiO₂, HfO₂, Al₂O₃, MgOₓ, CrO₂, VO, BN, and AlN.

62. A method for forming a plurality of nonvolatile memory cells, the method comprising the following steps:
forming a first plurality of substantially parallel, substantially coplanar conductors;
forming a first plurality of diodes above the first conductors;
forming a first plurality of reversible resistance-switching elements; and
forming a second plurality of substantially parallel, substantially coplanar conductors above the first diodes,
wherein the first reversible resistance-switching elements comprise a material selected from the group consisting of NiO, Nb₂O₅, TiO₂, HfO₂, Al₂O₃, MgOₓ, CrO₂, VO, BN, and AlN.

63. The method of claim 62 wherein the first conductors are formed above a substrate.

64. The method of claim 63 wherein the substrate comprises monocrystalline silicon.

65. The method of claim 62 wherein each of the first diodes is arranged in series with one of the first resistance-switching elements.

66. The method of claim 65 wherein the step of forming the first conductors comprises:
depositing a first layer or stack of conductive material;
patterning and etching the first layer or stack of conductive material to form first conductors; and
depositing dielectric fill between the first conductors.

67. The method of claim 66 wherein the step of forming the first diodes comprises:
depositing a semiconductor layer stack above the first conductors and dielectric fill; and
patterning and etching the semiconductor layer stack to form the first diodes.

68. The method of claim 67 wherein the semiconductor layer stack comprises silicon, germanium, or alloys thereof.

69. The method of claim 65 wherein the step of forming the first resistance-switching elements comprises depositing a layer of resistance-switching material above the first conductors, the layer comprising a material selected from the group consisting of NiO, Nb₂O₅, TiO₂, HfO₂, Al₂O₃, MgOₓ, CrO₂, VO, BN, and AlN.

70. The method of claim 69 wherein the step of forming the first resistance-switching elements further comprises patterning and etching the layer of resistance-switching material in the same patterning and etching step used to pattern and etch the first diodes.

71. The method of claim 65 wherein the first conductors comprise aluminum.

72. The method of claim 65 wherein the first conductors comprise tungsten.

73. The method of claim 65 wherein the first diodes are in the form of vertically oriented pillars.

74. The method of claim 65 wherein the step of forming the second conductors comprises:
depositing a second layer or stack of conductive material; and
patterning and etching the second layer or stack of conductive material to form second conductors.

75. The method of claim 74 wherein the step of forming the first resistance-switching elements comprises depositing a layer of resistance-switching material above the first diodes, the layer comprising a material selected from the group consisting of NiO, Nb₂O₅, TiO₂, HfO₂, Al₂O₃, MgOₓ, CrO₂, VO, BN, and AlN.

76. The method of claim 75 wherein the step of forming the first resistance-switching elements further comprises patterning and etching the layer of resistance-switching material in the same patterning and etching step used to pattern and etch the second conductors.

77. The method of claim 65 wherein the second conductors comprise aluminum.

78. The method of claim 65 wherein the second conductors comprise tungsten.

79. A method for forming a monolithic three dimensional memory array, the method comprising the following steps:
a) forming a first memory level above a substrate, the first memory level formed by a method comprising:
i) forming a first plurality of diodes; and
ii) forming a first plurality of reversible resistance-switching elements comprising material selected from the group consisting of NiO, Nb₂O₅, TiO₂, HfO₂, Al₂O₃, MgOₓ, CrO₂, VO, BN, and AlN, wherein each of the first diodes is arranged in series with one of the resistance-switching elements; and
b) monolithically forming at least a second memory level above the first memory level and above the substrate.

80. The method of claim 79 wherein the substrate comprises monocrystalline silicon.

81. The method of claim 79 wherein, in each of the first resistance-switching elements is above one of the first diodes.

82. The method of claim 79 wherein, in each of the first resistance-switching elements is below one of the first diodes.

83. The method of claim 79 wherein the step of forming the first memory level further comprises:
forming a first plurality of substantially parallel, substantially coplanar conductors; and
forming a second plurality of substantially parallel, substantially coplanar conductors wherein the second conductors are above the first conductors.

84. The method of claim 83 wherein the first conductors or the second conductors comprise tungsten.

85. The method of claim 83 wherein the first conductors or the second conductors comprise aluminum.

86. The method of claim 83 wherein the first memory level comprises a first plurality of memory cells, wherein each memory cell comprises a portion of one of the first conductors, one of the first diodes, one of the resistance-switching elements, and a portion of one of the second conductors.

87. The method of claim 83 wherein the step of forming the first conductors comprises:
depositing a first layer or stack of conductive material above the substrate; and
patterning and etching the first layer or stack of conductive material to form the first conductors.

88. The method of claim 83 wherein the step of forming the first diodes comprises:
depositing a first semiconductor layer stack above the first conductors and intervening dielectric gap fill; and
patterning and etching the first semiconductor layer stack to form the first diodes.

89. The method of claim 88 wherein the semiconductor layer stack comprises germanium, silicon, or alloys thereof.

90. The method of claim 88 wherein the step of patterning and etching the first semiconductor layer stack to form the first diodes comprises patterning and etching the semiconductor layer stack to form a first plurality of pillars.

91. The method of claim 83 wherein the step of forming the second conductors comprises:
depositing a second layer or stack of conductive material above the first diodes; and
patterning and etching the second layer or stack of conductive material to form the second conductors.

92. The method of claim 79 wherein the step of forming the first plurality of resistance-switching elements comprises depositing a first layer of resistance-switching material.

93. The method of claim 79 wherein the step of monolithically forming at least the second memory level above the first memory level comprises depositing a second layer of resistance-switching material above the substrate.

94. A method for forming a monolithic three dimensional memory array, the method comprising the following steps:
forming a first plurality of substantially parallel, substantially coplanar conductors at a first height above a substrate and extending in a first direction;
forming a second plurality of substantially parallel, substantially coplanar conductors at a second height above the first height and extending in a second direction different from the first direction;
forming a first plurality of reversible resistance-switching elements comprising a material selected from the group consisting of NiO, Nb₂O₅, TiO₂, HfO₂, Al₂O₃, MgOₓ, CrO₂, VO, BN, and AlN;
forming a first plurality of diodes, wherein the first diodes and the first resistance switching elements are above the first height and below the second height;
forming second diodes above the second conductors; and
forming third conductors above the second conductors.

95. The method of claim 94 wherein the monolithic three dimensional memory array comprises a first plurality of memory cells, each first memory cell comprising one of the first diodes and one of the resistance-switching elements arranged in series between one of the first conductors and one of the second conductors.

96. The method of claim 94 further comprising a second plurality of resistance-switching elements comprising a material selected from the group consisting of NiO, Nb₂O₅, TiO₂, HfO₂, Al₂O₃, MgOₓ, CrO₂, VO, BN, and AlN, the second resistance-switching elements formed above the second conductors.

97. The method of claim 94 wherein the third conductors are above the second diodes.

98. The method of claim 94 further comprising a fourth plurality of substantially parallel, substantially coplanar conductors above the second diodes.

99. The method of claim 98 wherein the second diodes are above the third conductors.

100. The method of claim 94 wherein the substrate comprises monocrystalline silicon.

101. A method for forming a nonvolatile memory cell, the method comprising:
forming a first conductor;
forming a second conductor;
forming a reversible resistance-switching element; and
forming a diode, wherein the diode and the reversible resistance-switching element are disposed electrically in series between the first conductor and the second conductor,
and wherein, during formation of the first and second conductors, diode, and switching element and crystallization of the diode, temperature does not exceed about 500 degrees C.

102. The method of claim 101 wherein the reversible resistance-switching element comprises a material selected from the group consisting of NiO, Nb₂O₅, TiO₂, HfO₂, Al₂O₃, MgOₓ, CrO₂, VO, BN, and AlN.

103. The method of claim 101 wherein the temperature does not exceed about 475 degrees C.

104. The method of claim 101 wherein the temperature does not exceed about 425 degrees C.

105. The method of claim 101 wherein the temperature does not exceed about 400 degrees C.

106. The method of claim 101 wherein the temperature does not exceed about 375 degrees C.

107. The method of claim 101 wherein the temperature does not exceed about 350 degrees C.

108. The method of claim 101 wherein the diode comprises a semiconductor material, the semiconductor material consisting of germanium or a germanium alloy.

109. The method of claim 108 wherein the germanium alloy is at least 80 atomic percent germanium.

110. The method of claim 109 wherein the germanium alloy is at least 90 atomic percent germanium.

111. The method of claim 109 wherein the diode is a semiconductor junction diode.

112. The method of claim 108 wherein the semiconductor material is substantially polycrystalline.

113. The method of claim 101 wherein the first conductor or the second conductor comprises an aluminum layer.

114. The method of claim 101 wherein the first conductor or the second conductor comprises a copper layer.

115. The method of claim 101 wherein the substrate comprises monocrystalline silicon.

116. A method for forming a monolithic three dimensional memory array, the method comprising:
i) forming a first memory level above a substrate, the first memory level comprising a plurality of first memory cells, each first memory cell comprising:
a) a reversible resistance-switching element; and
b) a diode, wherein the temperature during formation of the first memory level does not exceed about 475 degrees C.; and
ii) monolithically forming at least a second memory level about the first memory level.

117. The method of claim 116 wherein the resistance-switching element of each first memory cell comprises a material selected from the group consisting of NiO, Nb₂O₅, TiO₂, HfO₂, Al₂O₃, MgOₓ, CrO₂, VO, BN, and AlN.

118. The method of claim 116 wherein the diode comprises semiconductor material, wherein the semiconductor material is germanium or a germanium alloy.

119. The method of claim 118 wherein the semiconductor material is at least 80 atomic percent germanium.

120. The method of claim 119 wherein the semiconductor material is at least 90 atomic percent germanium.

121. The method of claim 118 wherein the semiconductor material is substantially polycrystalline.

122. The method of claim 118 wherein the first memory level further comprises a plurality of first conductors and a plurality of second conductors, the second conductors formed above the first conductors,
wherein each first memory cell comprises a portion of one of the first conductors and a portion of one of the second conductors,
wherein the first conductors or the second conductors comprise an aluminum layer or a copper layer.

123. A nonvolatile memory cell comprising:
a diode comprising semiconductor material, wherein the semiconductor material diode is germanium or a germanium alloy; and
a reversible resistance-switching element.

124. The nonvolatile memory cell of claim 123 wherein the resistance-switching element comprises a material selected from the group consisting of NiO, Nb₂O₅, TiO₂, HfO₂, Al₂O₃, MgOₓ, CrO₂, VO, BN, and AlN.

125. The nonvolatile memory cell of claim 123 wherein the germanium alloy is at least 20 atomic percent germanium.

126. The nonvolatile memory cell of claim 125 wherein the germanium alloy is at least 50 atomic percent germanium.

127. The nonvolatile memory cell of claim 126 wherein the germanium alloy is at least 80 atomic percent germanium.

128. The nonvolatile memory cell of claim 123 wherein the semiconductor material is germanium.

129. The nonvolatile memory cell of claim 123 further comprising a bottom conductor and a top conductor, wherein the diode and the resistance-switching element are arranged in series between the bottom conductor and the top conductor and the top conductor is above the bottom conductor.

130. The nonvolatile memory cell of claim 129 wherein the top conductor or the bottom conductor comprises a copper layer or an aluminum layer.

131. A monolithic three dimensional memory array comprising:
i) a first memory level formed above a substrate, the first memory level comprising a plurality of first memory cells, each first memory cell comprising:
a) a reversible resistance-switching element; and
b) a diode, the diode comprising a semiconductor material, wherein the semiconductor material is germanium or a germanium alloy; and
ii) at least a second memory level monolithically formed above the first memory level.

132. The monolithic three dimensional memory array of claim 131 wherein the resistance-switching element comprises a material selected from the group consisting of NiO, Nb₂O₅, TiO₂, HfO₂, Al₂O₃, MgOₓ, CrO₂, VO, BN, and AlN.

133. The monolithic three dimensional memory array of claim 131 wherein the germanium alloy is at least 20 atomic percent germanium.

134. The monolithic three dimensional memory array of claim 133 wherein the germanium alloy is at least 50 atomic percent germanium.

135. The monolithic three dimensional memory array of claim 133 wherein the germanium alloy is at least 80 atomic percent germanium.

136. The monolithic three dimensional memory array of claim 131 wherein the diode is a semiconductor junction diode.

137. The monolithic three dimensional memory array of claim 136 wherein the diode is a p-i-n diode.

138. The monolithic three dimensional memory array of claim 136 wherein the diode is a Zener diode.

139. The monolithic three dimensional memory array of claim 131 wherein the first memory level further comprises:
a first plurality of substantially parallel, substantially coplanar conductors extending in a first direction and formed above the substrate; and
a second plurality of substantially parallel, substantially coplanar conductors extending in a second direction and formed above the first conductors,
wherein each first memory cell further comprises a portion of one of the first conductors and a portion of one of the second conductors, and
in each memory cell the diode and the resistance-switching element are disposed between one of the first conductors and one of the second conductors.

140. The monolithic three dimensional memory array of claim 139 wherein the first conductors or the second conductors comprise an aluminum layer or a copper layer.

141. A monolithic three dimensional memory array comprising:
i) a first memory level formed above a substrate, the first memory level comprising a plurality of first memory cells, each first memory cell comprising:
a) a first bottom conductor formed above the substrate, the first bottom conductor comprising a layer of aluminum, an aluminum alloy, or copper;
b) a reversible resistance-switching element; and
c) a diode formed above the first bottom conductor; and
ii) at least a second memory level monolithically formed above the first memory level.

142. The monolithic three dimensional memory array of claim 141 wherein the reversible resistance-switching element comprises a material selected from the group consisting of NiO, Nb₂O₅, TiO₂, HfO₂, Al₂O₃, MgOₓ, CrO₂, VO, BN, and AlN.

143. The monolithic three dimensional memory array of claim 141 wherein the diode is formed of germanium or a germanium alloy.

144. The monolithic three dimensional memory array of claim 143 wherein the diode is polycrystalline.
